(19) United States
(12) Patent Application Publication
(10) Pub. No.: US 2009/0255808 A1
(43) Pub. Date: Oct. 15, 2009

(54) TARGET FOR EFFICIENT USE OF PRECIOUS DEPOSITION MATERIAL

(75) Inventor: Jeffrey Shane Reiter, Palo Alto, CA (US)

Correspondence Address: SEAGATE TECHNOLOGY LLC;C/O NOVAK DRUCE & QUIGG LLP, 1000 LOUISIANA, Fifty-Third Floor, HOUSTON, TX, 77002, US

(73) Assignee: Seagate Technology LLC, Scotts Valley, CA (US)

(21) Appl. No.: 12/420,952

(22) Filed: Apr. 9, 2009

Related U.S. Application Data
(60) Provisional application No. 61/044,362, filed on Apr. 11, 2008.

(51) Int. Cl. C23C 14/35

(52) U.S. Cl. 204/298.12

(57) ABSTRACT

Aspects comprise sputtering targets comprising a base material carrier provided with a recessed pattern, such as a looping trench, to receive a more precious material to be sputtered during deposition processes. The looping trench can have a cross-section of varying depth based on an expected variation in the magnetic field. The more precious material is provided at least in the trench, for example by hot pressing, and also can be pressed into a layer across an entirety of a surface of the carrier. During operation, the desired deposition of the precious material can occur from the trench area. Thus, a higher percentage of the precious material in the target is used, reducing inventory costs. The base material can be selected based on characteristics of the more precious material, and based on goals including reducing diffusion of base material into precious material and galvanic reactions.

### CROSS REFERENCE TO RELATED APPLICATION

This application claims priority from U.S. provisional application No. 61/044,362, entitled “TARGET FOR EFFICIENT USE OF PRECIOUS DEPOSITION MATERIAL”, filed on Apr. 11, 2008, which is incorporated by reference in its entirety, for all purposes, herein.

### BACKGROUND

1. Field

The present invention generally relates to sputtering and physical vapor deposition, and more particularly to targets used in such processes.

2. Description of Related Art

Deposition of materials onto a substrate using sputtering processes is well known. Sputtering typically involves material removal from a target material by its bombardment with highly energized ions formed after high energy electrons are emitted from the target material by placing a high RF or DC voltage between the target and the substrate to be coated. These emitted electrons ionize processed gas such as argon placed within a vacuum chamber after it has been substantially evacuated.

The processed gas ions then form a plasma, an electrically neutral association of electrons and positive ions. The plasma is caused by the emitting of electrons from the target material. The plasma ions accelerate and strike the target causing atoms to be ejected from the target material. The dislodged atoms deposit on the substrate, forming, over time, a thin film of target material on the substrate. The substrate to be coated may comprise a semiconductor layer or a laminate used in the manufacture of magnetic recording media, for example.

Some example sputtering processes use a DC magnetron sputtering process, particularly for applications where a thin film material deposition of a precisely controlled thickness and within narrow atomic fraction tolerances on a substrate is desired. In one common configuration, a racetrack-shaped magnetic field is applied to the sputter target by placing magnets on the backside surface of the target. Electrons are trapped near the sputter target, improving argon ion production and increasing the sputtering rate. As explained above, ions within this plasma collide with a surface of the sputter target causing the sputter target to emit atoms from the sputter target surface. The voltage difference between the cathodic sputter target and an anodic substrate that is to be coated causes the emitted atoms to form the desired film on the surface of the substrate.

Unfortunately, the magnetic field ordinarily is not uniform over the surface of the target, and this non-uniformity contributes to uneven usage of the target. As the target surface becomes more uneven, variations in material deposition and other undesirable effects can result, which requires replacement of the target. Materials used in targets can often be expensive. Therefore, after a target has been “end-of-lifed”, it can be recycled so that the material can be used to produce a new target. It is not unusual for a target to be unsuitable for sputtering due to surface abnormalities caused by the uneven magnetic field strength after only a relatively small proportion of the target material has been removed and deposited on the substrate. Targets can potentially be refilled, but such refilling can have undesirable effects, such as allowing impurities or other abnormalities to exist or be propagated in a refilled target. One result of inefficient target usage is that large amounts of expensive target material often must be kept in inventory at significant expense. Thus, there exists a need for more efficient usage of the target material.

### SUMMARY

Embodiments and aspects include a target for use in a vapor deposition apparatus. The target comprises a carrier formed of a first material. The carrier includes a first surface with a trench defined therein. The trench can have a contour that substantially matches a distribution of intensity of a magnetic containment field upon the target during use of the target in the vapor deposition apparatus.

In some embodiments, a depth of a cross-section profile of the trench varies so that deeper trench depth is substantially aligned with higher intensity regions of the magnetic containment field during use of the target in the vapor deposition apparatus. A second material that is to be deposited during usage of the target is disposed upon the first surface including the trench so as to cover the first surface. The second material has greater thickness where it overlies the trench than in other portions of the first surface overlain by the second material.

The cross-section of the trench is generally deeper where a higher intensity magnetic field is expected, such that a depth of the second material is greater where the intensity is higher. The first material may be Molybdenum and the second material may be Ruthenium.

Other aspects include machines using such targets, and methods for producing such targets. For example, a method for producing a deposition target may comprise providing a carrier formed of a first substance, and having a first surface. The method also may comprise determining an expected shape and variation in intensity of a magnetic containment field established during vapor deposition using the target in a deposition apparatus, and forming a cavity on the first surface conforming to the expected shape of the magnetic field, a depth of the cavity varying with the expected variation in magnetic field intensity; and pressing a particulate material for deposition into the cavity.

It is preferable that there be a determination or an estimate as to an intensity of the magnetic field, and that determination should be used in determining a cross-section depth of the trench. This approach is expected to yield higher utilization of the deposition material, which is far more expensive than the carrier material. However, some benefits of the invention also can be derived by providing a trench having a flat bottom, for example. Or, by further example, a bottom can be curved (i.e., deeper in some portions) without particular regard to an expected field intensity. In such embodiments, a depth of the trench is selected to avoid exposing the carrier material at the quickest eroding portion of the target. Since different magnetrons and deposition apparatus can be characterized or experimented with to at least heuristically determine these parameters, a person of ordinary skill can complete embodiments of the invention according to the disclosures herein.

Some aspects include a plasma deposition configuration, which may comprise a substrate having a first surface upon which particles of a deposition material are to be deposited, and a target having a generally planar second surface formed of the material to be deposited.

The target comprises a carrier supporting the deposition material with a surface formed to include a looping trench around the planar second surface. The carrier is formed of a material different from the deposition material.

The configuration comprises a magnetron apparatus to establish a magnetic field in a pattern for urging ions and electrons into proximity of the second surface. A strength of the magnetic field may vary from a low strength proximate a center of the second surface, increasing and then decreasing near the periphery. The looping trench in the carrier preferably is formed to have a cross-section of varying depth, and the depth of the cross-section varying based on an expected strength of the magnetic field at that point in the cross-section.

In any of the above aspects, the target material for deposition can include Ruthenium and a material used to form the carrier can include Molybdenum.

The target carriers can have a trench comprising a generally race track shaped contour including first and second curved end sections connected by generally linear middle sections.

Although preferably a trench bottom of the carrier is tailored for a magnetic field intensity that will be used during sputtering, targets can also include a trench of an arbitrary profile, including a flat bottom. In such targets, either the target would be used only to the point where the fastest eroding point hits the trench bottom (i.e., erodes all the deposition material at that point), which can be determined by observation during usage, or by experimentation, or the trench can be formed to a depth that can be determined based on a desired amount of usage.

### BRIEF DESCRIPTION OF THE DRAWINGS

For a fuller understanding of aspects and examples disclosed herein, reference is made to the accompanying drawings in the following description.

FIG. 1 illustrates an example vapor deposition system configuration including a magnetron, a target, and a substrate;

FIG. 2 illustrates a planar target composed of a material for deposition according to the prior art;

FIG. 3 illustrates an example of results of an analysis of a predicted and experimented erosion pattern in a circular target;

FIG. 4 illustrates a schematic cross-section of a target with an example of magnetic field strength lines superimposed, and a variable erosion pattern caused by the variable magnetic field strength;

FIGS. 5A-5C illustrate aspects of a carrier formed of a first material for supporting a second target deposition material;

FIG. 6 illustrates steps in a process according to FIGS. 7A-7D;

FIGS. 7A-7D illustrate aspects of forming a completed target comprising a carrier of a first material supporting a configuration of a second material for deposition; and

FIGS. 8A-8B illustrate aspects of the completed target according to FIGS. 7A-7D.

### DETAILED DESCRIPTION

The following description is presented to enable a person of ordinary skill in the art to make and use various aspects of the inventions. Descriptions of specific techniques, implementations and applications are provided only as examples. Various modifications to the examples described herein may be apparent to those skilled in the art, and the general principles defined herein may be applied to other examples and applications

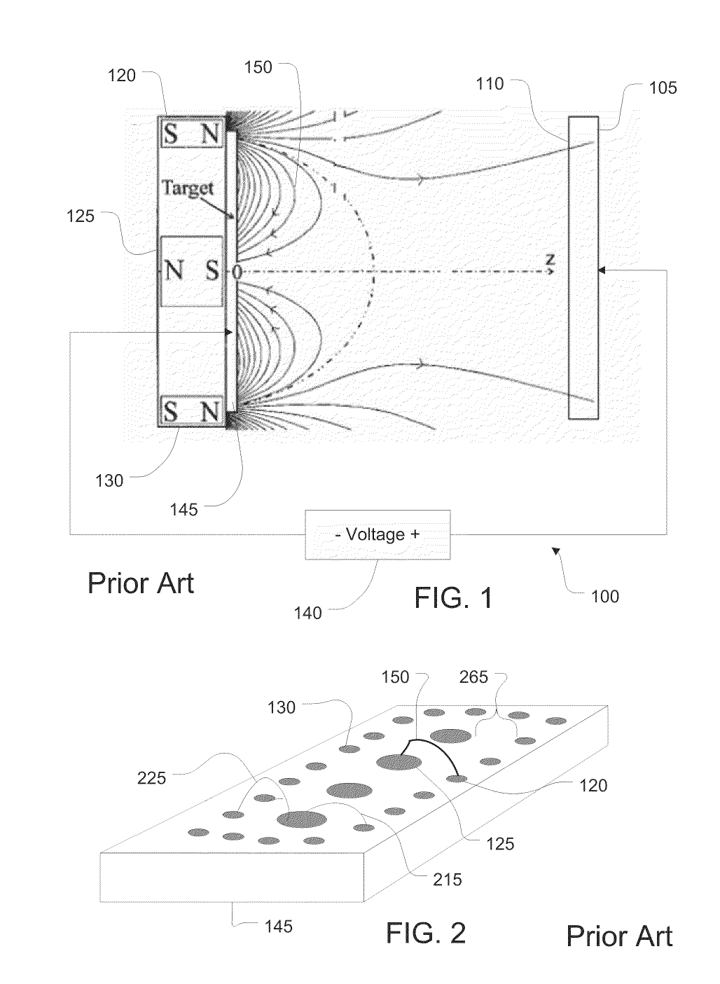

FIG. 1 illustrates a cross-section of a vapor deposition system configuration 100 including center magnet 125, and outer (periphery) magnets 120 and 130 that form a magnetron, a target 145, and a substrate 105. This configuration 100 can be a cross section of a circular or an elongated deposition system. Target 145 is formed from the material desired to be deposited on a first surface 110 of substrate 105. Target 145 can be composed of a variety of materials, some of them are relatively cheap, for example, aluminum, while others are very expensive, such as gold, and platinum-series metals and compounds of such metals. A voltage source 140 establishes an electric potential between target 145 and substrate 105. Magnets 120, 125, and 130 form a magnetic field with field lines (e.g., field line 150) traveling between center magnet 125 and outer magnets 120 and 130.

FIG. 2 shows an example relative disposition of target 145, center magnet 125, and outer magnets 120 and 130. Other inner and outer magnets are illustrated and not separately numbered. Field line 150 is illustrated, as well as field lines 225 and 215. As can be discerned, the arrangement of magnets shown in FIG. 2 serves to retain charged particles, such as ions and electrons. For the elongated planar target 145, this containment area is conveniently called a “racetrack.” As will be appreciated, the magnetic field has a varying intensity from an inner part to an outer part of the racetrack. Where the magnetic field has a higher intensity, more ions are confined and so material to be deposited is eroded more rapidly from a surface area 265 of target 145 in those higher intensity regions than in other regions.

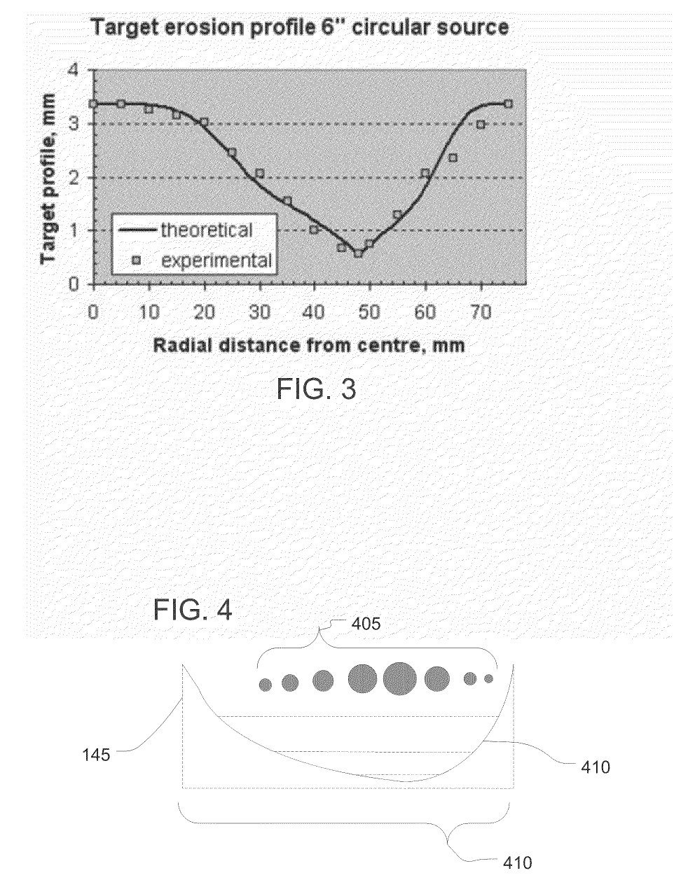

FIG. 3 shows an example of such varying erosion characteristics for a circular target. As is evident, based on a given setup, a theoretical and an experimental erosion profile generally agree. Here, the radial distance from the center can be considered analogously to area 265 of FIG. 2 in that an erosion profile in area 265 from center to outer may be similar to the profile of FIG. 3, and such profile can be determined for a particular arrangement of magnets and other apparatus.

FIG. 4 illustrates a part of target 145. Circles 405 represent variation in magnetic field strength across area 265 (trench profile) corresponding with an erosion profile 410. Larger diameter circles among circles 405 represent regions of higher magnetic field intensity.

A great deal of work has been focused on trying to cause erosion profiles to be more even over a cross-section of target 145 (or stated otherwise, attempting to produce an even wear pattern across a target). Improvements have been made in this area. However, a large portion of a target is often not used before the target no longer can serve as a source for deposition material. Whatever material remaining in the target can be recycled or in some cases refilled to produce a new target. Since this material is expensive, costs are incurred to possess a metal that ultimately will be recycled, and even if the targets are refilled, the storage cost of maintaining a target comprised entirely of a precious material is high.

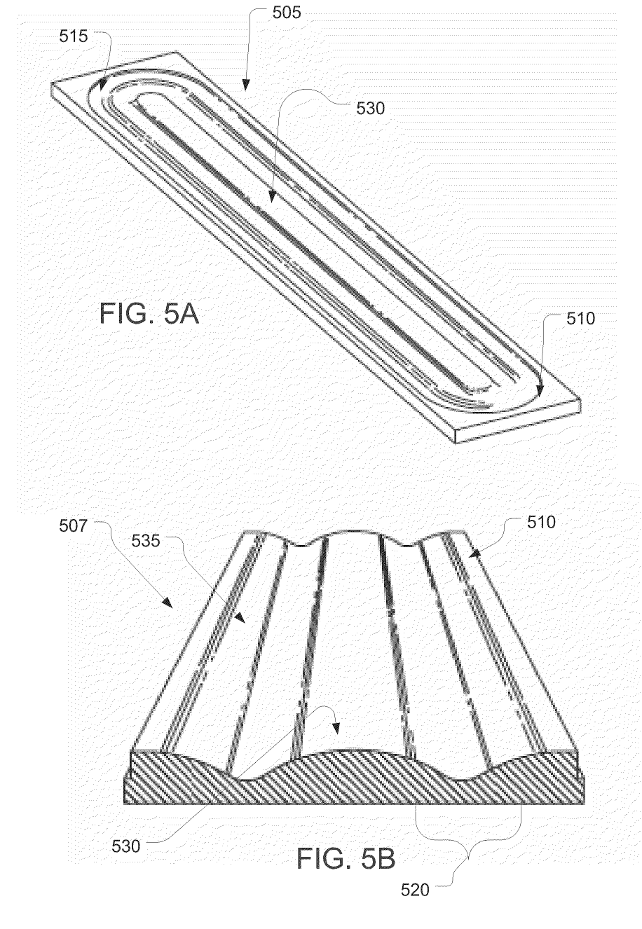

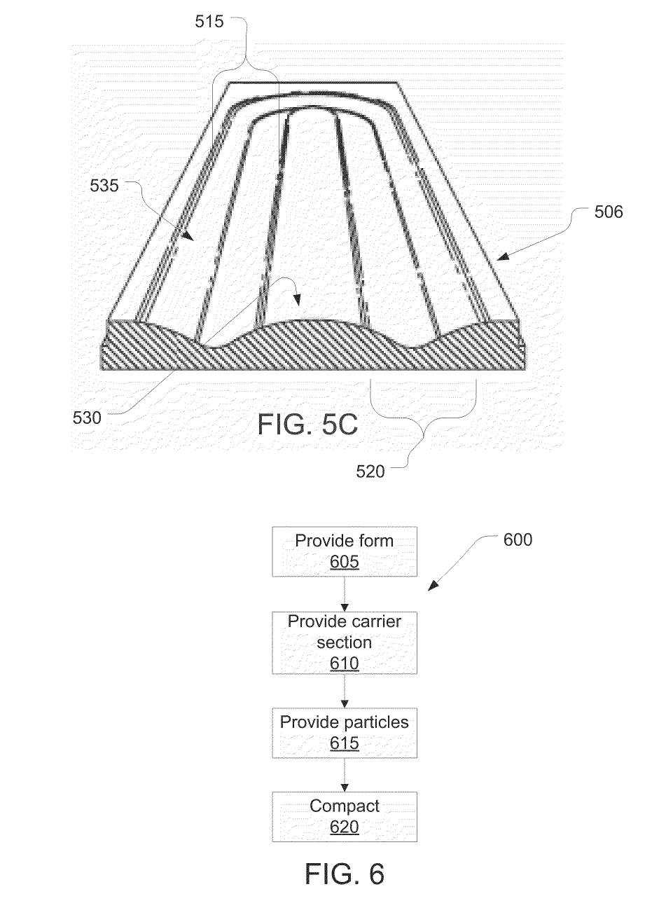

FIGS. 5A-5C illustrate aspects of a carrier 505 that can be used in a target addressing these considerations in accordance with some exemplary aspects. Carrier 505 is formed of a relatively inexpensive first material, which can be selected based on a precious material desired to be deposited in a given situation. For example, carrier 505 can be formed of Molybdenum if Ruthenium is desired to be used as a second material, i.e. as the deposition material. Considerations for selection of a material for carrier 505 can include matching Coefficients of Thermal Expansion (CTE) for each material, and that the carrier material be able to bond with the material for deposition. For example, CTE for Molybdenum is generally around 3×10⁻⁶ inches per degree F., while Ruthenium is generally 5.1×10⁻⁶ inches per degree F. Other considerations include that the carrier 505 material should be thermally and electrically conductive. Also, it should be difficult for the carrier 505 material to diffuse into the material for deposition, and there should be no pronounced chemical or galvanic reactions between the materials.

In this example, carrier 505 can be generally rectangular and includes a first surface 510, in which a trench 515 is formed (carriers can be provided in other shapes, such as circles). As illustrated, carrier 505 can be formed in multiple pieces, for example with end pieces, such as end piece 506 (FIG. 5C), and intermediate section 507 (FIG. 5B). Two end pieces can be provided for a three-piece carrier. When these pieces are connected, they form a functionally unitary carrier 505. Trench 515 extends through the pieces 506, 507 and has a cross-section 520. The trench can have a ‘racetrack’ contour that includes a pair of relatively long, straight, parallel, side-by-side paths that are interconnected with curved segments so as to form one continuous path. Cross-section 520 can extend from proximate a center portion 530 of carrier 505 to a periphery 535 thereof (and more generally, can be tailored to an expected or an experimental erosion profile for the sputtering machine in which the target is expected to be used).

A profile (i.e., a depth variable with distance between center portion 530 and periphery 535) of cross-section 520 can be selected based on an expected or measured intensity of magnetic field for a particular deposition apparatus, a magnetron used in deposition apparatuses, or to a specification for a profile. For example, an erosion rate can be specified for various points along cross-section 520, and given a desired amount of operating time, a depth at each point along the cross-section 520 can be estimated. Then, a guard band of some depth can also be provided to account for any differences in measurement error, estimation error, as well as other considerations. One consideration is whether and how far the material used to form carrier 505 can diffuse into the material to be diffused.

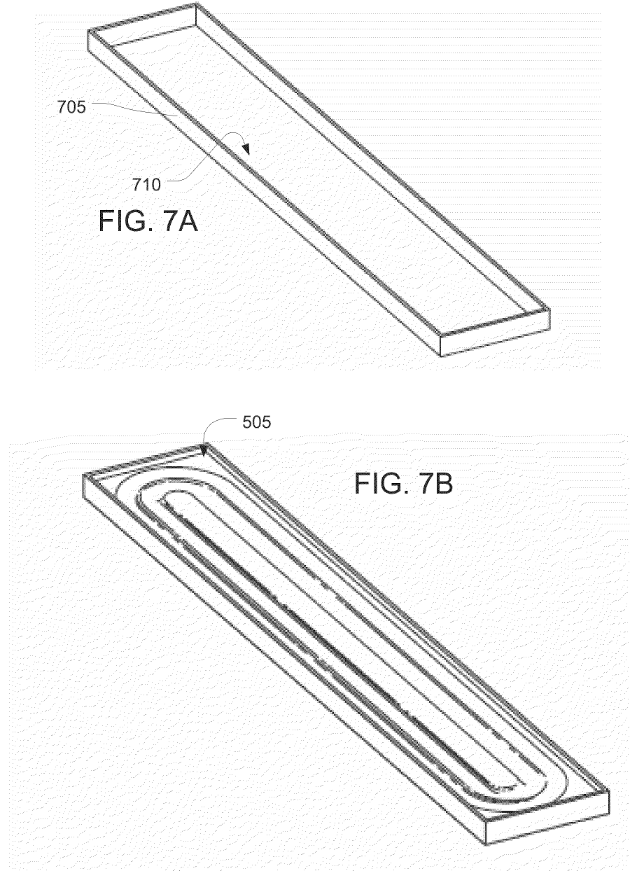

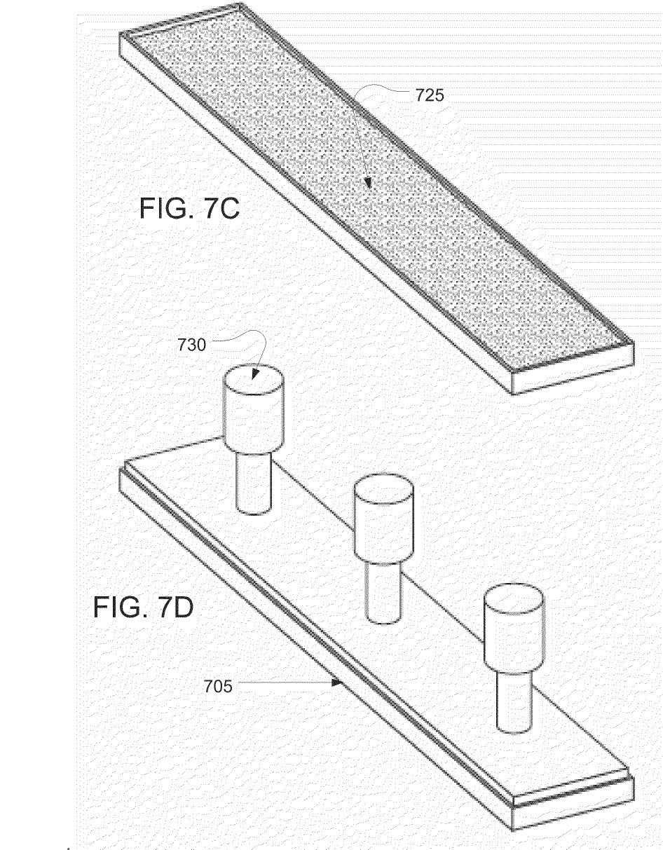

FIG. 6 depicts steps of a process 600 process to form a target comprising a carrier formed of a first material and a precious material deposited in the carrier. Process 600 is also explained with respect to FIGS. 7A-7D, which depict examples of structures that can be used in process 600.

FIG. 6 illustrates steps of a process 600 that may be used in conjunction with components depicted in FIGS. 7A-7D. Process 600 includes providing (step 605) a form 705 (FIG. 7A) in which a carrier will be placed. Form 605 can be made of carbon. Method 600 also includes providing or otherwise disposing (step 710) a carrier or a section (e.g., FIGS. 5A and 5B) thereof into form 705, providing (step 615) particles 725 of the material for deposition in a quantity sufficient to fill the trench and preferably provide a complete layer of such deposition material on the surface of the carrier or carrier section (e.g., to present a surface of the material to be deposited). Then, material 725 is compacted (step 620), such as by using a press 730 operating under heat and pressure to solidify the particles of deposition material and adhere the solidified deposition material to the carrier 710 (or the carrier section). Press 730 may be formed of a material compatible with the material desired to be pressed. The carrier itself can be pressed or formed in a mold to develop a trench as desired in the carrier (e.g., the press can have a mirror image contour to that desired for the trench to be formed). Alternatively, the carrier can be milled or otherwise machined to arrive at a desired trench profile.

FIGS. 7A-7D illustrate componentry that can be used in processes according to FIG. 6, which are for forming a target comprising a carrier formed of a first material and a second material, more precious than the first and for deposition. FIG. 7A depicts form 705 with an open top 710 and a press 730 configured to press into the form 705 from open top 710. To enable a sustained pressure, the press 730 forms a seal with form 705. FIG. 7B illustrates carrier 505 disposed in form 705. FIG. 7D illustrates that a loose particulate material 725 to be deposited is disposed in form 705. An amount of material deposited should be enough to fill the trench and preferably also is enough to provide an entire layer of the material for deposition over the top surface of carrier 505, such that the top surface (not illustrated) of the completed target exposes only deposition material and no carrier material. FIG. 7D illustrates that press 715 has compacted the loose particulate matter into the trench.

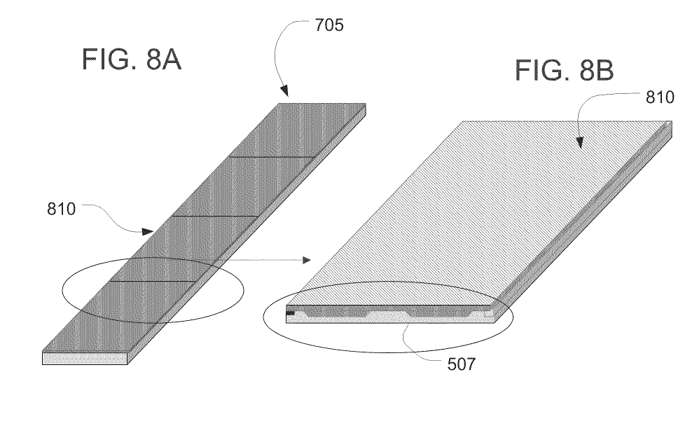

FIG. 8A illustrates carrier 505 formed of end portions and intermediate portions, as described with respect to FIGS. 5A-C and as may be produced with the apparatus of FIGS. 7A-7D and per method 600. FIG. 8B illustrates an intermediate section 810 with carrier section 507 and the solidified deposition material 840. The intermediate section 810 includes that carrier 507 is formed of the first inexpensive material defining parallel trench segments in regions expected to be subjected to the highest magnetic field intensity (see FIG. 5B). The more expensive second material that is to be removed during sputtering fills the trench segments and covers a first surface of the carrier so as to form a substantially flat surface. The depth of the second material coating the first surface of the carrier is deeper in regions where the trench segments are formed. These are the regions of greatest expected magnetic field intensity. Thus, the more expensive material that is to be removed for deposition is thickest in the regions of the target that will be exposed to the greatest magnetic field intensity. FIG. 8B illustrates a generally flat-bottomed trench; however curved bottoms or more complicated, experimentally, or theoretically obtained shapes can be determined.

Therefore, a target in accordance with embodiments of the invention concentrates the second material in target regions where the second material is likely to erode the most rapidly. Other target regions that are likely to be exposed to a lesser magnetic field have a thinner coating of the second material. The trench defined in the carrier, which is formed of the less expensive first material, facilitates this more efficient distribution of the more expensive second material. The more efficient use of the second material reduces the amount of that material that is unused and thereby reduces the amount of the second material that need be kept in inventory.

It is preferable that there be a determination or estimate as to an intensity of the magnetic field, and that determination should be used in determining a cross-section depth of the trench. This approach is expected to yield higher utilization of the deposition material, which is far more expensive than the carrier material. However, some benefits of the invention also can be derived by providing a trench having a flat bottom, or a bottom curved without particular regard to field intensity expected in a particular deposition machine, for example. In such embodiments, a depth of the trench is preferably selected to avoid exposing the carrier material at the quickest eroding portion of the target. Where the trench bottom does not conform as precisely as may be possible to the field intensity, some residual expensive deposition material would generally remain, so it is preferable to tailor trench bottom, where practical. Since different magnetrons and deposition apparatus can be characterized or experimented with to at least heuristically determine these parameters, a person of ordinary skill can complete embodiments of the invention according to the disclosures herein.

Many variations and enhancements to the examples and aspects disclosed herein will be apparent to those of ordinary skill in the art in view of these disclosures. For example, the contour of the trench may be more rounded and less elongated. All such variations and enhancements should therefore be considered within the scope of the appended claims and their equivalents.

I claim:

1. A target for use in a vapor deposition apparatus, comprising:
a carrier formed of a first material, and having a first surface with a trench defined therein; and
a second material, more precious than the first material, deposited as a particulate into the trench and compacted under heat and pressure to solidify the deposited particulate for usage as a source of the second material during deposition processes.

2. The target of claim 1, wherein the contour includes a trench depth that varies according to an expected intensity of the magnetic containment field during use of the target in the vapor deposition apparatus, the depth being deeper in regions of expected higher intensity.

3. The target of claim 1, wherein the trench is contoured to have a generally flat bottom.

4. The target of claim 1, wherein the trench is contoured to have a curved bottom.

5. The target of claim 1, wherein the carrier is generally rectangular, and the trench is in a general shape of a race track, includes generally co-parallel and linear middle sections connected by curved end sections.

6. The target of claim 5, wherein the carrier is formed from a plurality of independently processed sections.

7. A method for producing a deposition target, comprising:
providing a carrier formed of a first material and having a first surface;
defining a cavity in the first surface, the cavity being deeper where a magnetic field intensity is expected to be greater during usage of the target in a deposition process; and
pressing a second material, more precious than the first material, into the cavity so that the second material can be sputtered from the carrier when using the target during a deposition process while the first material is substantially unsputtered.

8. The method of claim 7, further comprising estimating an expected magnetic containment field intensity pattern during vapor deposition using the target in a deposition apparatus; and selecting a cross-section for the cavity based on the expected field intensity pattern.

9. The method of claim 7, further comprising forming the cavity with a flat bottom, and selecting a depth of the cavity to avoid exposing the first material at the quickest eroding portion of the target at a desired target lifetime, based on characterizations of sputtering equipment.

10. The method of claim 7, further comprising forming the cavity with a curved bottom, a deepest portion of the cavity formed to coincide with an expected maximum intensity region of the expected field intensity pattern.

11. The method of claim 8, further comprising selecting the first material to have little diffusivity into the second material.

12. The method of claim 7, further comprising pressing the second material under heat into the cavity.

13. The method of claim 7, further comprising providing a layer of the second material over an entirety of the first surface of the carrier, which will be exposed during the deposition process.

14. The method of claim 7, further comprising selecting the first material to have a coefficient of thermal expansion compatible with the second material.

15. A plasma deposition configuration comprising:
a substrate having a first surface upon which particles of a precious deposition material are to be deposited;
a target having a generally planar second surface of the deposition material, the target comprising a carrier supporting the deposition material with a surface formed to include a trench following the plane of the second surface, the carrier formed of a material less precious than the deposition material;
a magnetron apparatus to establish a magnetic field in a pattern for urging ions and electrons into proximity of the second surface, a strength of the magnetic field varying from a low strength proximate a central portion of the second surface, increasing and then decreasing near a periphery of the second surface,
wherein the trench in the carrier and the magnetic field pattern are co-established so that a deepest portion of the trench is generally co-extensive with a highest intensity region of the field pattern.

16. The configuration of claim 15, wherein the trench has a generally flat bottom, and the trench depth is selected based on a maximum intensity region of the field.

17. The configuration of claim 15, wherein the trench has a curved flat bottom, and a deepest portion of the trench is selected to generally coincide with a maximum intensity region of the field.
